(19) United States
(12) Patent Application Publication
(10) Pub. No.: US 2018/0315605 A1
(43) Pub. Date: Nov. 1, 2018

(54) Method for Ion Implantation

(71) Applicant: Advanced Ion Beam Technology, Inc., Hsin-Chu (TW)

(72) Inventor: Steven Raymond Walther, Andover, MA (US)

(21) Appl. No.: 15/911,521

(22) Filed: Mar. 5, 2018

Related U.S. Application Data
(60) Provisional application No. 62/491,579, filed on Apr. 28, 2017.

(51) Int. Cl. H01L 21/265

(52) U.S. Cl. CPC H01L 21/26586; H01L 21/26513

(57) ABSTRACT

A method for ion beam implantation is provided. The method provides an ion implantation with a multiple-geometric-orientation ion beam that accommodates a range of tilt angles. The range of tilt angles can be defined with a dose distribution specified across the range of tilt angles. The method comprises: acquiring ion implantation parameters, determining the number of exposure steps, selecting implantation parameters corresponding to the exposure steps, acquiring implantation data, defining a first implantation sequence, creating a multiple-geometric-orientation implant exposure sequence according to the first implantation sequence, and performing the ion implantation according to the multiple-geometric-orientation implant exposure sequence.

### FIELD OF THE INVENTION

The invention relates to a method for performing a single implant to implant ions on a wafer with multiple geometric orientations, that accommodates a series of exposure steps with predetermined tilt angles, implant doses/dose fractions, wafer rotations, and wafer temperatures.

### BACKGROUND OF THE INVENTION

In the field of ion implantation and 3D structure doping, such as with sidewall doping of a wafer device, such as a Fin Field-Effect Transistor (FinFET), it has become increasingly difficult to perform doping and ion implantation for advanced nodes due to the tight Fin pitch and high aspect ratio posed by the structure. There is also a degree of variation in Fin structures both locally and across the wafer, combined with ion implant angle repeatability tolerances that provide poor results when using a single fixed tilt angle for ion beam relative to wafer.

Implant species include atomic and molecular ions. In cases where the implant energy is low and beam current is limited, it may particularly advantageous to use molecular ions with multiple atoms of the desired species, such as SiF3+ (SiF4 gas precursor) for a fluorine implant.

Wan et al. (U.S. Pat. No. 9,431,247) provides a method for implantation, which provides and implants an integrated divergent beam (IDB) into a workpiece or wafer having one or more three-dimensional structures. This IDB method provides that the IDB may be perpendicularly implanted into the workpiece or tilted implanted into the workpiece.

The IDB method is limited to angles produced by the beam crossover, and is very difficult to tune with poor repeatability. The IDB method provides a range of tilt angles with a very limited range, and provides no alteration on the dose distribution by angle.

To address this problem, multiple implants at different tilt angles could be used, but that is much more costly as it takes more time to run on an ion implanter.

### SUMMARY OF THE INVENTION

To address the above problems of the art, the present invention provides a method for a single ion implantation with a multiple exposure sequence/multiple geometric orientation that accommodates a range of tilt angles. The range of tilt angles can be defined along with a dose distribution specified across the range of tilt angles. The multiple exposure sequence/multiple geometric orientation approach overcomes the problems of the prior art and allows for full control over the range of tilt angles available and the amount of dose distributed across the range of tilt angles. This provides a more capable solution to the difficult geometries and fabrication induced variation of the geometry for 3D structure doping.

In an embodiment of the invention, the method for ion implantation of a wafer utilizes a parallel 1D beam, where the implant is done with a range of tilt angles and other parameters in a single implant, where the range of title angles and other parameters are either from user inputs or selected from predetermined database entries.

In an embodiment of the invention, the method for ion implantation comprises the steps of: acquiring ion implantation parameters, determining a number of exposure steps, selecting implantation parameters corresponding to the exposure steps, acquiring implantation data, defining a first implantation array, creating a multiple-geometric-orientation implant exposure sequence according to the first implantation array, and performing the ion implantation according to the ion implantation exposure sequence.

In an embodiment of the invention, the step of defining a first implantation array comprises creating a sequence of ion implantation steps according to a dosage fraction, an angle of the wafer relative to the ion beam, an orientation of the wafer, and the temperature of the wafer.

In an embodiment of the invention, the implantation parameters may comprise a bi-mode or quad-mode wafer tilt/rotation capability to facilitate 3D structure doping. In an embodiment, the bi-mode wafer tilt/rotation comprises performing half of the ion implantation exposures perpendicular to the wafer, rotating the wafer by 180 degrees, and performing the second half of the ion implantation exposures.

In an embodiment of the invention, the first set of the ion implantation exposures correspond to the second set of the ion implantation exposures. More specifically, an equal number of exposure steps may be performed in the first orientation and the second orientation. The exposure steps of the first orientation and the exposure steps of the second orientation may be configured to use the same set of parameters.

The method allows for ion implantation to be performed according to exposure steps, and each exposure step may specify its own dose fraction, wafer angle, wafer orientation, temperature and other parameters. By using the above method, various wafer geometries and ion implantation requirements can be accommodated.

Following description and figures are disclosed to better understand of the advantages of the present invention.

### BRIEF DESCRIPTION OF THE DRAWINGS

FIG. 1 is a flowchart of the method for ion implantation with a multiple-geometric-orientation ion beam.

FIG. 2 is a table comprising the array of parameters for the method for ion implantation with a multiple-geometric-orientation ion beam.

FIG. 3 is an exemplary table comprising the array of parameters for the method for ion implantation with a multiple-geometric-orientation ion beam.

FIG. 4 is a flowchart of another embodiment of the method for ion implantation with a multiple-geometric-orientation ion beam.

### DETAILED DESCRIPTION OF THE PREFERRED EMBODIMENT

Aspects, features and advantages of several exemplary embodiments of the present invention will become better understood with regard to the following description in connection with the accompanying drawings. It should be apparent to those skilled in the art that the described embodiments of the present invention provided herein are illustrative only and not limiting, having been presented by way of example only. All features disclosed in this description may be replaced by alternative features serving the same or similar purpose, unless expressly stated otherwise. Therefore, numerous other embodiments of the modifications thereof are contemplated as falling within the scope of the present invention as defined herein and equivalents thereto. Hence, use of absolute terms, such as, for example, “will,” “will not,” “shall,” “shall not” “must,” and “must not,” are not meant to limit the scope of the present invention as the embodiments disclosed herein are merely exemplary.

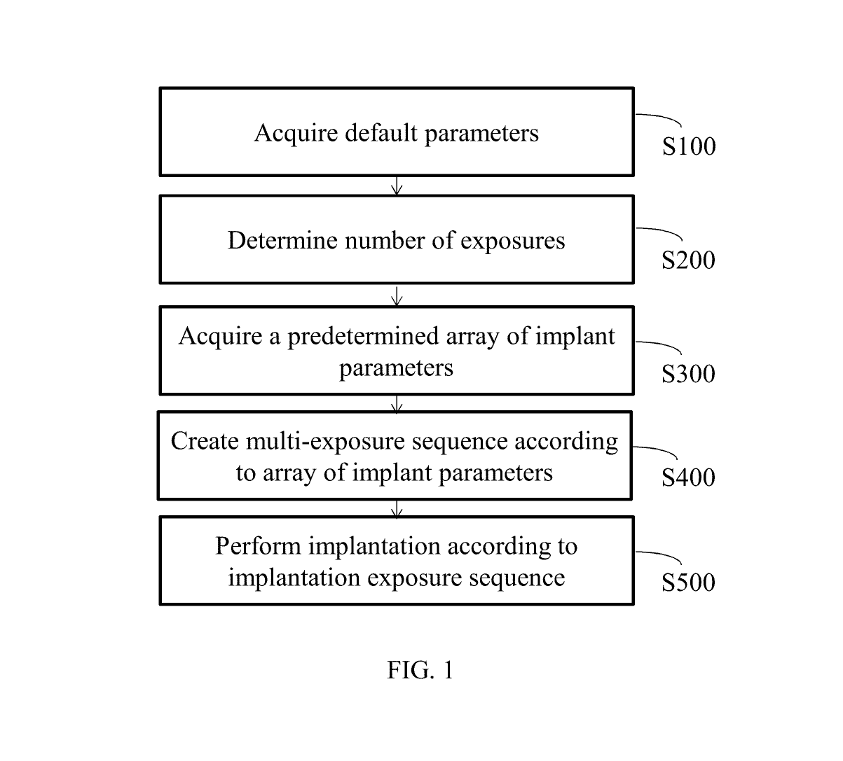

Refer to FIG. 1 showing a flow chart of the method for ion implantation with a multiple-geometric-orientation ion beam. The present invention provides a method for ion implantation comprising the steps of: acquiring standard/default implant parameters S100, determining the number of exposures S200, determining a sequence of exposures S300, creating an implantation exposure sequence S400, and performing the ion implantation according to the implantation exposure sequence S500.

In an embodiment of the invention, S100 comprises acquiring standard/default implant parameters either from a user input or from a memory. The implant parameters may comprise the ion species, ion energy, dose, tilting angles, default target orientation or/and target orientations. In an embodiment, the implant parameters may further comprise a wafer temperature, and dosage rate.

The implant parameters may be used to indicate an initial or default setting for the ion species, ion energy, total dose of the ion implant, the default tilt angle, default wafer orientation, and default operation mode.

The ion species indicates which species of ion to be used for the implantation. In an embodiment, this ion species may comprise SiF3+ (SiF4 gas precursor). Other ion species may be used according to different implants.

Ion energy and dose indicate the total energy of the ion beam and the amount of ion to be used during the implantation. The default target orientation determines the initial orientation of the wafer relative to the ion beam.

In an embodiment, the wafer tilt angle is measured according to the change in wafer position about a first axis and/or a second axis relative to the ion beam, and the wafer orientation is measured according to the change in wafer rotation relative to the wafer normal vector or an axis perpendicular to the plane of the wafer.

The implant parameters may further comprise an array of parameters (or functional relationship) indicating the dose, the wafer angle relative to the ion beam, the wafer orientation relative to the beam, the wafer temperature and other wafer related parameters. The array of parameters may be associated according to the number of exposures.

The values of the implant parameters may be determined according to the geometry of the wafer or substrate to be implanted.

In an embodiment of the invention, S200 comprises determining the number of exposures or the exposure count for the ion implantation. The number of exposures may be according to a user input or from a memory. In an embodiment, the number of exposures indicates how many exposure steps will be performed during the ion implantation step.

In another embodiment, the number of exposures may correspond to time points during the ion implantation, and the duration between any given two time points can be either constant or varied. The exposure step may correspond to an interval of time during the ion implantation.

Step S300 comprises acquiring a predetermined array of parameter sets to create the multi-exposure sequence. In an embodiment, the predetermined array of parameters is acquired from a database in a computer system. In an embodiment, this step further comprises determining the functional relationship between dose, wafer angle relative to the beam, wafer orientation relative to the beam, wafer temperature, and other wafer related parameters.

In an embodiment, the array of parameters comprises a series of sets of modifications to the initial or default implant parameters. Furthermore, in the step of determining the exposure sequence, the method may use the initial or default parameters when the array of parameters does not specify an exact setting. As an example, if the wafer temperature is not defined in the pre-determined array, the exposure sequence refers to the default wafer temperature of the default implant parameters.

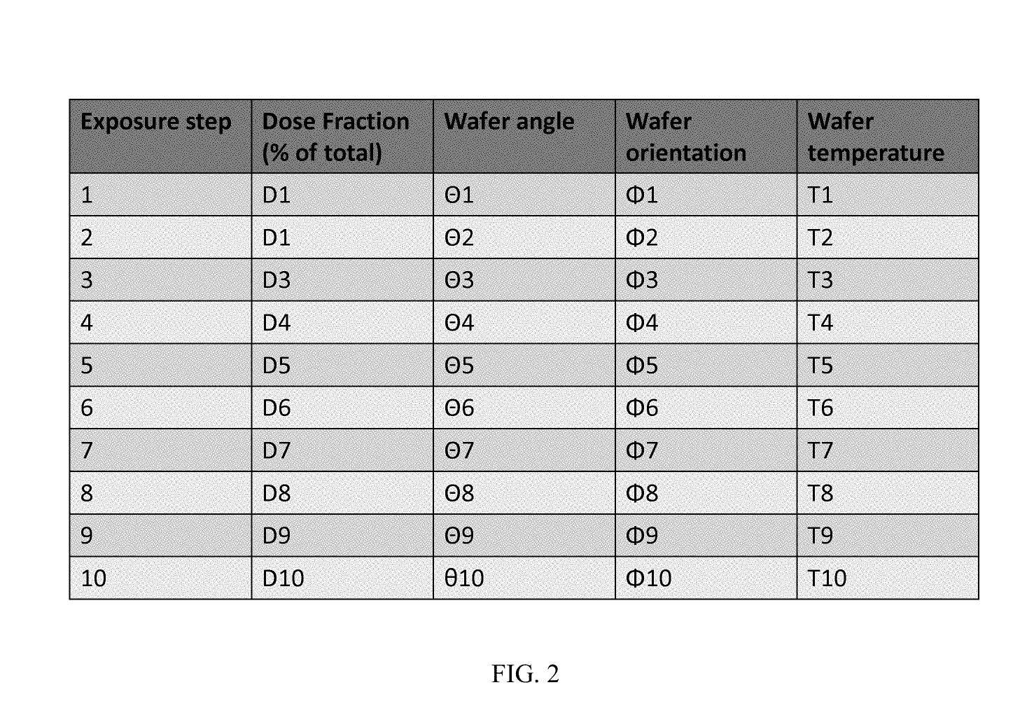

Referring to FIG. 2, an exemplary array of parameters is provided. The array of parameters associates an exposure step with a dose fraction, a wafer angle relative to the ion beam, a wafer orientation relative to the ion beam, and a wafer temperature. The dose fraction refers to the percentage of the total dose of the implant performed by the ion beam, the wafer angle corresponds to the tilting of the wafer during the multi-exposure ion implantation, the wafer orientation refers to how the wafer is oriented relative to the beam, and the wafer temperature indicates the temperature that the wafer is held at during the corresponding exposure step.

In an embodiment of the invention, the implant dose may be distributed within the range of tilt angle. The implant dose may be selectively configured to be uniformly distributed or adjusted by each specified tilt angle. For example, a shallower wafer angle may be configured to receive a lower percentage of the total dose. One of ordinary skill in the art would recognize that other implant doses may be specified according to the wafer geometry and ion implantation requirements

In an embodiment of the invention, the tilt variation can be in discrete steps (for example, by degree), or it may be a continuous variation of the tilt during the wafer scan. For example, the tilt variation can be five degree increments between exposure steps, or performed over the continuous range of tilt angles.

In an embodiment, the array of parameters may correspond to a bi-mode or quad-mode for wafer tilt and/or orientation. In the bi-mode wafer tilt/orientation corresponds to performing half of the ion implantation exposures perpendicular to the wafer, rotating the orientation of the wafer by 180 degrees, and performing the second half of the ion implantation exposures. One of ordinary skill in the art would recognize the number of degrees described herein is an exemplary embodiment and other wafer orientations may be used according to the wafer geometry and ion implantation requirements.

In an embodiment of the invention, the first set of the ion implantation exposures corresponds to the second set of the ion implantation exposures. More specifically, an equal number of exposure steps may be performed in the first orientation and the second orientation. The exposure steps of the first orientation and the exposure steps of the second orientation may be configured to use the same set of parameters.

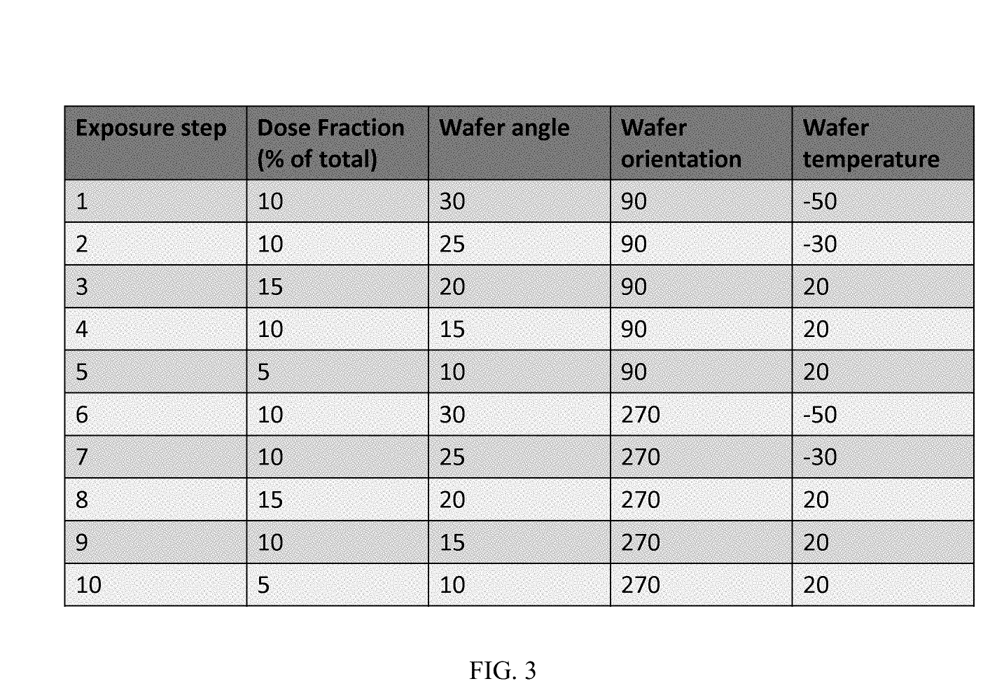

Referring to FIG. 3, an exemplary array of parameters for a bi-mode tilt/orientation ion implantation is provided. The exposure steps correspond to a first set or mode, and a second set or mode of exposure steps.

In FIG. 3, the first set of exposure steps comprise the exposure steps 1-5; and the second set of exposure steps comprise the exposure steps 6-10. In exposure step 6, the wafer orientation will be rotated by 180 degrees. In FIG. 3, the first set of the exposure step parameters correspond to the parameters of the second set of the exposure steps. For example, exposure step 6 comprises a same dose fraction and wafer tilt angle as exposure step 1.

Similarly, in a quad-mode tilt/orientation ion implantation, the wafer orientation may be rotated by 90 degrees, and the exposure steps may be divided into four sets of exposure steps. One of ordinary skill in the art would recognize the number of degrees described herein is an exemplary embodiment and other wafer orientations may be used according to the wafer geometry and ion implantation requirements.

In an embodiment, the rotation of the wafer orientation determined by the bi-mode or quad-mode tilt/orientation ion implantation may be configured according to the implantation requirements of the wafer.

Referring to FIG. 1, Step S400 comprises creating a multi-expo sure sequence corresponding to the array of parameters of step S300. The multiple-geometric-orientation exposure sequence comprises a set of instructions for the ion implantation apparatus.

In step S500, the ion implantation is performed according to the multi-exposure sequence. The ion beam implanting system for performing the implantation may comprise an ion implantation apparatus comprising a control circuit, an ion beam source, a tilting/rotating stage for the wafer, and a temperature controller. The control circuit may read the multiple-geometric-orientation exposure sequence, and perform the ion implantation according to the exposure steps of the array of parameters.

Accordingly, referring to FIGS. 2 and 3, the ion implantation is performed according to the first exposure step at the wafer angle, dose fraction, wafer orientation, and temperature associated with the first exposure step. Each subsequent step iterates through the array of parameters of the multiple-geometric-orientation exposure sequence.

During the ion implantation, the dose fraction indicates the percentage of the total ion dose to be implanted during an exposure step. The dose fraction may be regulated by controlling the power of the ion beam, the duration of the exposure of the ion beam.

Additionally, during each exposure step of the ion implantation process, the wafer is tilted relative to the ion beam according to the wafer angle specified by the multiple-geometric-orientation exposure sequence and the corresponding exposure step. Similarly, the temperature of the wafer may also be regulated at each exposure step according to the temperature specified by the multiple-geometric-orientation exposure sequence.

In an embodiment, the ion implantation may be performed continuously by interpolating the array of parameters or in discrete exposure steps according to the array of parameters. For example, as the exposure steps of FIG. 3 are discontinuous, the ion implantation may perform an additional linear interpolation of exposure step 1 and exposure step 2 to calculate the desired dose fraction, wafer tilt angle, and temperature to be used during the continuous ion implantation between the time interval of exposure step 1 and exposure step 2.

In an embodiment, the ion implantation may use ions with multiple atoms of the desired species, such as SiF3+ (SiF4 gas precursor) for a fluorine implant.

In an embodiment, ion beam diagnostics such as determining the beam angle spread, may be incorporated to determine the true distribution of implant angles. The true distribution of implant angles may be accounted for during step S500, such that the implant angle and dose distribution better match the desired implant angle/dose range specified by the array of parameters.

In an embodiment, the beam diagnostics may be combined with implant reporting to provide information after the ion implantation of the ion angle distributions across the wafer and correlated with device results. This information may be stored in a memory to be retrieved for a subsequent ion implantation and used to adjust the array of parameters for a subsequent ion implantation to better optimize the performance of the multiple-geometric-orientation implant exposure sequence.

In an embodiment, the ion implantation may use the beam diagnostics information to modify the multiple-geometric-orientation exposure sequence to compensate for device and wafer variation to achieve more consistent ion implantation across many different lots of wafers.

In an embodiment, the method for ion implantation using a ion beam with a multi-exposure sequence may be performed by an ion implantation apparatus. The apparatus may comprise a processor, a non-transitory storage media, a user input interface executed either by hardware or software, an ion beam source, and a stage for positioning the wafer.

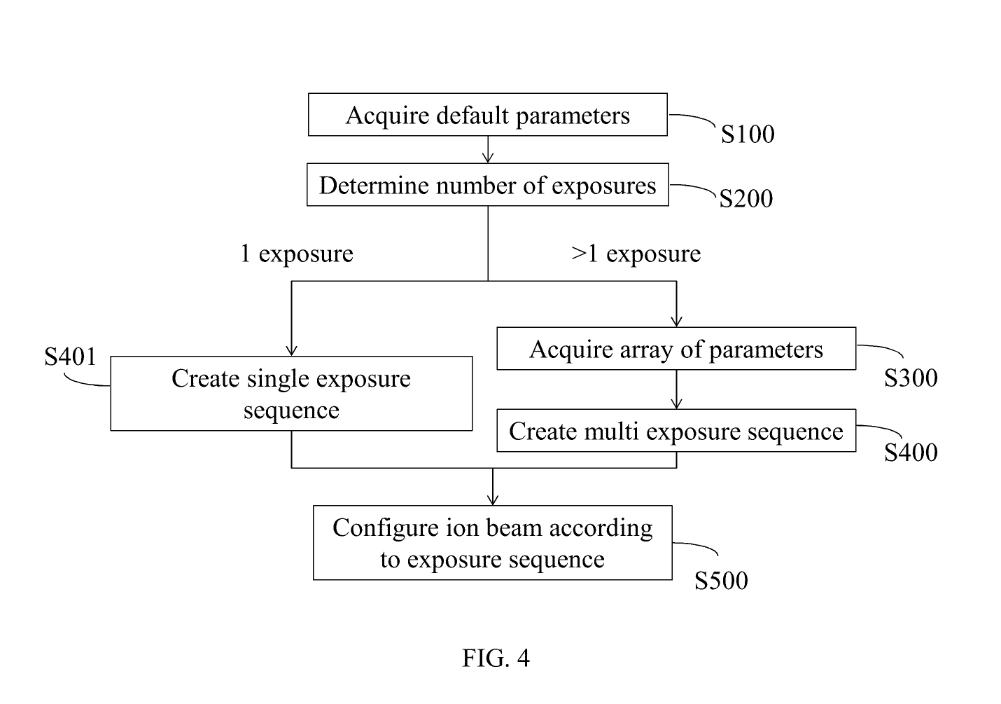

Referring to FIG. 4, another embodiment of the method is shown. Similarly to FIG. 1, Step S100 comprises acquiring default implant parameters either from a user input or from a memory. The implant parameters may comprise the ion species, ion energy, dose, tilting angles, default target orientation or/and target orientations. In an embodiment, the implant parameters may further comprise a wafer temperature, and dosage rate.

The implant parameters may be used to indicate an initial or default setting for the ion species, ion energy, total dose of the ion implant, the default tilt angle, default wafer orientation, and default operation mode.

In an embodiment of the invention, S200 comprises determining the number of exposures for the ion implantation. The number of exposures may be according to a user input or from a memory. In an embodiment, the number of exposures indicates how many exposure steps will be performed during the ion implantation step.

Furthermore, when the number of exposures determined in Step S200 comprises a single exposure, step S401 is performed. Step S401 comprises creating a single exposure sequence according to the default implant parameters.

When the number of exposures is greater than one, steps S300 and S400 are performed, which is equivalent to step S300 and S400 of FIG. 1, respectively.

After the exposure sequence is created in either step S400 or S401, step S500 is performed. When the exposure sequence is a single exposure sequence, the ion beam is configured to perform a single exposure according to the implant parameters. When the exposure sequence is a multiple exposure sequence, step S500 is equivalent to step S500 of FIG. 1.

In summation, the present invention provides a method for ion implantation using a multiple-geometric-orientation ion beam. The method determines parameters for the exposures of the ion beam, which comprise dose fraction, tilt angle, and wafer orientation. The method tilts and rotates the wafer in relation to the ion beam to allow for full control over the range of tilt angles available and the amount of dose distributed across the range of tilt angles. The present invention provides a more capable solution to the difficult geometries and fabrication induced variation of the geometry for 3D structure doping.

While the invention has been described in terms of what is presently considered to be the most practical and preferred embodiments, it is to be understood that the invention needs not to be limited to the above embodiments. On the contrary, it is intended to cover various modifications and similar arrangements included within the spirit and scope of the appended claims which are to be accorded with the broadest interpretation so as to encompass all such modifications and similar structures.

What is claimed is:

1. A method for implanting ions on a wafer with multiple geometric orientations, comprising:
acquiring a default parameter;
determining an exposure count;
acquiring a first set of implant parameters;
generating a multiple-geometric-orientation implant exposure sequence according to said exposure count, said default parameter, and said first set of implant parameters, wherein said multiple-geometric-orientation implant exposure sequence comprises a plurality of exposure steps;
implanting ions on said wafer according to said multiple-geometric-orientation implant exposure sequence;
wherein, each of said exposure steps specifies a dose percentage, a wafer angle, and a wafer orientation for an ion beam to implant ions.

2. The method according to claim 1, wherein said default parameter comprises an ion species to be used during said ion implantation, an energy of said ion beam, a total dose, and a default wafer orientation.

3. The method according to claim 2, wherein said first set of implant parameters comprises a target temperature for said wafer and a dosage rate.

4. The method according to claim 1, wherein said first set of implant parameters is retrieved from a memory.

5. The method according to claim 1, wherein said first set of implant parameters is specified according to a user input.

6. The method according to claim 1, wherein when the step of implanting ions is performed in a continuous mode, said step of implanting ions further comprises:
performing an interpolation of said dose percentage, said wafer angle, and said wafer orientation between each exposure step; and
implanting ions according to said interpolation.

7. A method for implanting ions on a wafer with multiple geometric orientations, comprising:
acquiring a default parameter;
determining an exposure count;
acquiring a first set of implant parameters;
determining an orientation mode, wherein said orientation mode comprises a first wafer orientation and a second wafer orientation;
generating a multiple-geometric-orientation implant exposure sequence according to said exposure count, said default parameter, said first set of implant parameters, and said orientation mode, wherein said multiple-geometric-orientation implant exposure sequence comprises a first array of a first plurality of exposure steps corresponding to said first wafer orientation and a second array of a second plurality of exposure steps corresponding to said second wafer orientation;
implanting ions on said wafer according to said multiple-geometric-orientation implant exposure sequence;
wherein, each of said exposure steps specifies a dose percentage, a wafer angle, and said wafer orientation for an ion beam to implant ions.

8. The method according to claim 7, wherein said default parameter comprises an ion species to be used during said ion implantation, an energy of said ion beam, a total dose, and a default wafer orientation.

9. The method according to claim 8, wherein said first set of implant parameters comprises a target temperature for said wafer and a dosage rate.

10. The method according to claim 7, wherein said first set of implant parameters is retrieved from a memory.

11. The method according to claim 7, wherein said first set of implant parameters is specified according to a user input.

12. The method according to claim 7, wherein when said step of implanting ions is performed in a continuous mode, the step of implanting ions further comprises:
performing an interpolation of said dose percentage, said wafer angle, and said wafer orientation between each exposure step; and
implanting ions according to said interpolation.

13. The method according to claim 7, wherein when said orientation mode comprises a bi-mode, said first wafer orientation and said second wafer orientation differ by a first rotation of said wafer, and said first plurality of exposure steps and said second plurality of exposure steps specify a same sequence of dose percentage and wafer angle.

14. The method according to claim 13, wherein said first rotation of said wafer comprises rotating said wafer orientation by 180 degrees.

15. The method according to claim 7, wherein when said orientation mode comprises a quad-mode, said operation mode further comprises a third wafer orientation and a fourth wafer orientation, and said multiple-geometric-orientation exposure sequence further comprises:
a third array corresponding to said third wafer orientation and a fourth array corresponding to said fourth wafer orientation, said third array comprising a third plurality of exposure steps and said first set of implant parameters, and said fourth array comprising a fourth plurality of exposure steps and said first set of implant parameters;
wherein, said first wafer orientation, said second wafer orientation, said third wafer orientation, and said fourth wafer orientation differ by a first rotation of said wafer, and said first plurality of exposure steps and said second plurality of exposure steps specify a same sequence of dose percentage and wafer angle.

16. The method according to claim 15, wherein said first rotation of said wafer comprises rotating said wafer orientation by 90 degrees.
